(19) United States
(12) Patent Application Publication
(10) Pub. No.: US 2026/0121794 A1
(43) Pub. Date: Apr. 30, 2026

(54) LINK ERROR CORRECTION CODE PARITY GENERATION IN X4-MODE FOR DYNAMIC RANDOM ACCESS MEMORY

(71) Applicant: Micron Technology, Inc., Boise, ID (US)

(72) Inventors: Naga Surya Anjan Kumar PUDI, Hyderabad (IN); Marco SFORZIN, Cernusco Sul Naviglio (IT)

(21) Appl. No.: 19/316,570

(22) Filed: Sep. 2, 2025

Related U.S. Application Data
(60) Provisional application No. 63/714,287, filed on Oct. 31, 2024.

(51) Int. Cl. H04L 1/00; H03M 13/11

(52) U.S. Cl. CPC H04L 1/0063; H03M 13/11

(57) ABSTRACT

A memory controller includes a communication interface including a plurality of data lines configured to transmit data according to an x4-mode configuration; and one or more processors configured to: split the data into a first data portion and a second data portion, generate first parity bits based on a first data portion and a transpose of a first reduced parity matrix corresponding to the first data portion, generate a first packet that includes the first data portion and the first parity bits, generate second parity bits based on a second data portion and a transpose of a second reduced parity matrix corresponding to the second data portion, generate a second packet that includes the second data portion and the second parity bits, and transmit the first packet and the second packet in two consecutive bursts on the plurality of data lines.

### CROSS-REFERENCE TO RELATED APPLICATION

This patent application claims priority to U.S. Provisional Patent Application No. 63/714,287, filed on Oct. 31, 2024, entitled “LINK ERROR CORRECTION CODE PARITY GENERATION IN X4-MODE FOR DYNAMIC RANDOM ACCESS MEMORY,” and assigned to the assignee hereof. The disclosure of the prior application is considered part of and is incorporated by reference into this patent application.

### TECHNICAL FIELD

The present disclosure generally relates to memory devices, memory device operations, and, for example, to link error correction code parity generation in x4-mode for dynamic random access memory.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, an electronic device may write to, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), holographic RAM (HRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source.

### BRIEF DESCRIPTION OF THE DRAWINGS

FIG. 1 is a diagram illustrating an example system associated with link error correction code (ECC) parity generation in x4-mode for DRAM.

FIG. 2 shows an example of a link ECC circuit of a memory controller according to one or more implementations.

FIG. 3 shows an example of a link ECC circuit of a memory device according to one or more implementations.

FIG. 4 is a flowchart of an example method associated with link error correction code parity generation in x4-mode for dynamic random-access memory.

### DETAILED DESCRIPTION

In memory systems, reliable data communication between different components, such as a memory controller and memory modules, is crucial to system performance and integrity. As system architectures evolve toward configurations such as x4-mode configurations, new challenges in data integrity and error correction arise. For example, a DRAM array may include 128 columns such that 128 bits of data can be transferred in or out of the DRAM array. Furthermore, current implementations may use eight data lines in an x8-mode configuration to transfer the 128 bits in a single memory operation (e.g., a write or read operation) with a burst length of 16. A link error correction code (ECC) operation may be performed for the x8-mode on the 128 bits using a Hamming code to generate 8 parity bits corresponding to the 128 bits. An additional single parity-check bit may be added to each byte or word of data to make a total number of Is either even (for even parity) or odd (for odd parity). The 8 parity bits (or 9 parity bits, when including the single parity-check bit) may be transmitted with the 128 bits during a data transfer. However, a memory system with an x4-mode configuration is not able to transfer 128 bits without increasing the burst length to 32, which is not practical or feasible in some memory systems.

A standard method for ensuring data integrity during memory transactions involves a process known as link ECC, which encodes additional parity bits with the data payload to detect and correct errors during data transmission. Link ECC is used to ensure data integrity over a data link between a memory controller and a memory module. One form of memory interface, low power double data rate 5 (LPDDR5), is often used in x8- or x16-modes in which eight or sixteen data lines (DQ lines) are used to transmit 128 bits of data at a time with ECC parity bits for error detection and correction.

However, while the existing link ECC solutions are well-suited for x8-mode operation in LPDDR5 components, there is no corresponding solution for x4-mode operation, where only four data lines (DQ lines) are used to transmit 64 bits of data with a burst length of 16. This presents a significant technical challenge, as conventional ECC encoding and decoding mechanisms are designed to handle 128-bit data widths commonly used in x8-mode configurations. The problem becomes even more complicated with the requirement that any new solution should be able to utilize the existing ECC circuitry to prevent the need for additional hardware that would otherwise increase the cost and complexity of the system. Specifically, there is a need to generate and process ECC parity for 64-bit data segments in x4-mode while avoiding additional ECC decode logic on both a DRAM side and a memory controller side of the memory system.

Some implementations described herein provide a method for managing link ECC parity in x4-mode for DRAM that enhances the efficiency of existing error-correcting mechanisms from a technical standpoint. For instance, a device such as a memory controller may receive a data vector and segment the data vector into a first data portion and a second data portion. The memory controller may subsequently utilize a reduced parity matrix corresponding to each portion to generate parity bits for that specific data portion, and generate respective packets associated with each data portion and a corresponding set of parity bits. These packets may be transmitted in two consecutive bursts, negating the requirement for supplementary circuitry. Moreover, the reduced parity matrix may be extrapolated from a parity check matrix used for 128-bit data transmissions, ensuring compatibility with the 64-bit data transmissions in the x4-mode configuration.

Further, the capabilities encompass both the memory controller and memory device, and include methodologies for generating corrected parity bits in the event that errors are detected through a computation of a syndrome vector, leveraging the error-correcting-code mechanisms pre-existing in the device.

Consequently, one or more implementations may be designed to fulfill the necessities of x4-mode DRAM operation in relation to ECC and parity bit generation. By capitalizing on the pre-existing ECC circuitry and implementing strategic amendments to the parity generation and error verification protocols, the solution circumvents the demand for supplementary decode logic hardware on the parts of both the memory and controller.

In this way, one or more implementations may facilitate a dependable operation of transferring data over an x4-mode communication interface with maximal efficiency and may avert a need for significant redesigns, which would otherwise contribute to escalated system expenditures and intricacy. It is also noteworthy that methodologies used in one or more implementations may incur minimal timing detriments and do not call for significant modifications to the LPDDR5 standard, hence maintaining performance and compatibility for x4 mode DRAM operations. This can lead to a reduction in raw materials and manufacturing resources required for additional hardware components. By the quality and reliability of the memory operation being refined by the methodologies described herein, an amount of resources utilized for manufacturing and maintaining DRAM is effectively reduced.

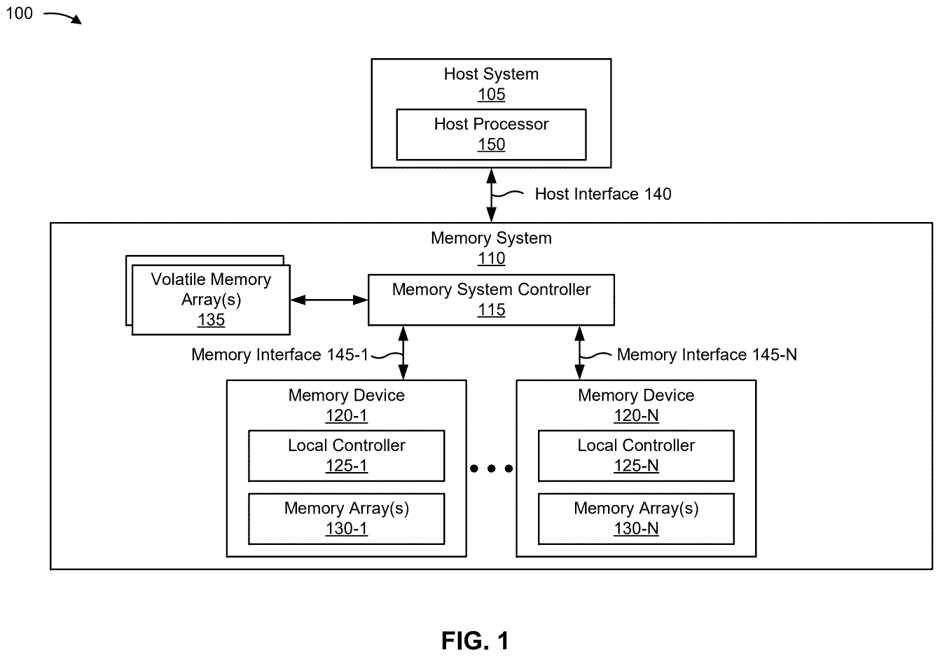

FIG. 1 is a diagram illustrating an example system 100 associated with link ECC parity generation in x4-mode for DRAM. The system 100 may include one or more devices, apparatuses, and/or components for performing operations described herein. For example, the system 100 may include a host system 105 and a memory system 110. The memory system 110 may include a memory system controller 115 and one or more memory devices 120, shown as memory devices 120-1 through 120-N (where N≥1). A memory device may include a local controller 125 and one or more memory arrays 130. The host system 105 may communicate with the memory system 110 (e.g., the memory system controller 115 of the memory system 110) via a host interface 140. The memory system controller 115 and the memory devices 120 may communicate via respective memory interfaces 145, shown as memory interfaces 145-1 through 145-N (where N≥1).

The system 100 may be any electronic device configured to store data in memory. For example, the system 100 may be a computer, a mobile phone, a wired or wireless communication device, a network device, a server, a device in a data center, a device in a cloud computing environment, a vehicle (e.g., an automobile or an airplane), and/or an Internet of Things (IoT) device. The host system 105 may include a host processor 150. The host processor 150 may include one or more processors configured to execute instructions and store data in the memory system 110. For example, the host processor 150 may include a CPU, a graphics processing unit (GPU), a field-programmable gate array (FPGA), an application-specific integrated circuit (ASIC), and/or another type of processing component.

The memory system 110 may be any electronic device or apparatus configured to store data in memory. For example, the memory system 110 may be a hard drive, a solid-state drive (SSD), a flash memory system (e.g., a NAND flash memory system or a NOR flash memory system), a universal serial bus (USB) drive, a memory card (e.g., a secure digital (SD) card), a secondary storage device, a non-volatile memory express (NVMe) device, an embedded multimedia card (eMMC) device, a dual in-line memory module (DIMM), a compute express link (CXL) memory module, and/or a random-access memory (RAM) device, such as a dynamic RAM (DRAM) device or a static RAM (SRAM) device.

The memory system controller 115 may be any device configured to control operations of the memory system 110 and/or operations of the memory devices 120. For example, the memory system controller 115 may include control logic, a memory controller, a system controller, an ASIC, an FPGA, a processor, a microcontroller, and/or one or more processing components. In some implementations, the memory system controller 115 may communicate with the host system 105 and may instruct one or more memory devices 120 regarding memory operations to be performed by those one or more memory devices 120 based on one or more instructions from the host system 105. For example, the memory system controller 115 may provide instructions to a local controller 125 regarding memory operations to be performed by the local controller 125 in connection with a corresponding memory device 120. Additionally, the memory system controller 115 may include additional components, such as one or more error correction code (ECC) engines (e.g., one or more ECC processors), such as for a purpose of detecting and/or correcting data errors to ensure data integrity and/or improve the overall reliability of the memory system 110. For example, the memory system controller 115 may include a single error correction (SEC) encoder and decoder or an SEC double error detection (SEC-DED) encoder and decoder.

A memory device 120 may include a local controller 125 and one or more memory arrays 130. In some implementations, a memory device 120 includes a single memory array 130. In some implementations, each memory device 120 of the memory system 110 may be implemented in a separate semiconductor package or on a separate die that includes a respective local controller 125 and a respective memory array 130 of that memory device 120. The memory system 110 may include multiple memory devices 120.

A local controller 125 may be any device configured to control memory operations of a memory device 120 within which the local controller 125 is included (e.g., and not to control memory operations of other memory devices 120). For example, the local controller 125 may include control logic, a memory controller, a system controller, an ASIC, an FPGA, a processor, a microcontroller, a CXL controller connected to DRAM, and/or one or more processing components. In some implementations, the local controller 125 may communicate with the memory system controller 115 and may control operations performed on a memory array 130 coupled with the local controller 125 based on one or more instructions from the memory system controller 115. As an example, the memory system controller 115 may be an SSD controller, and the local controller 125 may be a NAND controller. Additionally, the local controller 125 may include additional components, such as one or more ECC engines (e.g., one or more ECC processors), such as for a purpose of detecting and/or correcting data errors to ensure data integrity and/or improve the overall reliability of the memory system 110. For example, the local controller 125 may include an SEC encoder and decoder or an SEC-DED encoder and decoder.

A memory array 130 may include an array of memory cells configured to store data. For example, a memory array 130 may include a non-volatile memory array (e.g., a NAND memory array or a NOR memory array) or a volatile memory array (e.g., an SRAM array or a DRAM array). In some implementations, the memory system 110 may include one or more volatile memory arrays 135. A volatile memory array 135 may include an SRAM array and/or a DRAM array, among other examples. The one or more volatile memory arrays 135 may be included in the memory system controller 115, in one or more memory devices 120, and/or in both the memory system controller 115 and one or more memory devices 120. In some implementations, the memory system 110 may include both non-volatile memory capable of maintaining stored data after the memory system 110 is powered off, and volatile memory (e.g., a volatile memory array 135) that requires power to maintain stored data and that loses stored data after the memory system 110 is powered off. For example, a volatile memory array 135 may cache data read from or to be written to non-volatile memory, and/or may cache instructions to be executed by a controller of the memory system 110.

A volatile memory array 135 may be coupled to the memory system controller 115 by a communication interface (e.g., a communication link), such as a double data rate (DDR) link. For example, the DDR link may be a low-power double data rate (LPDDR) link, such as an LPDDR5 link. The communication interface may include a plurality of data lines configured to transmit data according to an x4-mode configuration, and a command line configured to transmit a command address that includes a command address bit CA0. In DRAM technology, the term “x4-mode” specifies a width of a data bus associated with each DRAM chip, which is directly related to the number of data lines (DQ lines) used for data transfer. The “x4” designation indicates that each DRAM chip has a 4-bit-wide data bus. Put another way, each memory device 120 may include four data lines (DQ lines) for transmitting four bits in parallel, with each data line transmitting one of the four bits. In x4-mode, each DRAM chip communicates data over four data lines. This means that each operation (read or write) involves transferring four bits of data simultaneously.

A burst length (BL) specifies an amount of data transferred in a single read or write operation, defined in terms of a number of data words. For example, a burst length of 16 means that 16 data words are transferred consecutively in one burst. Put another way, a burst length may be measured in a number of clock cycles. A burst length of 16 means that 16 clock cycles are used to transfer data in a single read or write operation, with one bit per data line being transmitted per clock cycle (e.g., data per cycle (in bits): 4 DQs×1 bit/DQ=4 bits). Thus, 64 bits may be transferred over a communication interface configured in x4-mode with a burst length of 16 (e.g., 4 bits/cycle×16 cycles=64 bits). Therefore, 64 bits may be transferred in a single read or write operation, which is initiated based on a corresponding read or write command provided to the local controller 125 by the memory system controller 115. The burst length determines how much data is transferred in one continuous sequence, impacting data throughput and access efficiency. The communication interface may be configured to transfer data according to a burst length of 16 clock cycles, such that 64 bits are transferred per memory operation. In some implementations, multiple bits may be transferred per cycle. For example, two bits per cycle may be read or written. Thus, only 8 cycles may be needed to transfer 64 bits. In other examples, such as LPDDR5, four bits or eight bits per cycle may be read or written, thus, requiring only 4 cycles or 2 cycles to transfer 64 bits. Thus, the communication interface may be configured to transfer data according to a desired transmission protocol. Additionally, the communication interface may include a command line configured to transmit a command address that includes a command address bit CA0.

The host interface 140 enables communication between the host system 105 (e.g., the host processor 150) and the memory system 110 (e.g., the memory system controller 115). The host interface 140 may include, for example, a Small Computer System Interface (SCSI), a Serial-Attached SCSI (SAS), a Serial Advanced Technology Attachment (SATA) interface, a Peripheral Component Interconnect Express (PCIe) interface, an NVMe interface, a USB interface, a Universal Flash Storage (UFS) interface, an eMMC interface, a DDR interface, a DIMM interface, and/or a CXL interface (e.g., a PCIe/CXL interface).

The memory interface 145 (e.g., a communication interface) enables communication between the memory system controller 115 and the memory device 120. The memory interface 145 may include a non-volatile memory interface (e.g., for communicating with non-volatile memory), such as a NAND interface or a NOR interface. Additionally, or alternatively, the memory interface 145 may include a volatile memory interface (e.g., for communicating with volatile memory), such as a DDR interface. For example, the memory interface 145 may be an LPDDR link, such as an LPDDR5 link, for enabling communication between the memory system controller 115 and the memory device 120 (e.g., volatile memory and/or the local controller 125 of the memory device 120). The memory interface 145 may include a plurality of data lines configured to transmit data according to an x4-mode configuration. Thus, the memory interface 145 may include four data lines (DQ lines). In addition, the memory interface 145 may be configured to transfer data according to a burst length of 16 clock cycles, such that 64 bits are transferred per memory operation.

The volatile memory array 135 may be configured to store data of a predetermined size (e.g., 128 bits). The data may be referred to as a data vector (e.g., a 128-bit data vector). Thus, during a write operation, it may be desirable to write, for example, 128 bits, into the volatile memory array 135. During a read operation, it may be desirable to read, for example, 128 bits, from the volatile memory array 135. However, due to constraints, including x4-mode and burst length, a parity computation utilized for data transfer is redesigned, along with a method of transferring the full amount of data, such that the data can be transferred within the constraints.

For example, during a write operation, the memory system controller 115 may split the data into a first data portion and a second data portion to be transferred in consecutive bursts, with each data portion being transferred with respective parity bits (e.g., 8 parity bits based on a Hamming code+a single parity-check bit). In some implementations, the data may be a 128-bit data vector, the first data portion may be a first half of the 128-bit data vector, including bits 1-64, and the second data portion may be a second half of the 128-bit data vector, including bits 65-128. Thus, the first data portion may be a first data sub-vector, the second data portion may be a second data sub-vector, and the first data sub-vector and the second data sub-vector may correspond to respective first and second halves of the data vector.

The volatile memory array 135 may include array portions configured to store the first data portion and the second data portion, respectively. For example, the volatile memory array 135 may include a first DRAM sub-array configured to store the first data portion and a second DRAM sub-array configured to store the second data portion. In some implementations, the first DRAM sub-array may include a first plurality of array columns of the volatile memory array 135 and the second DRAM sub-array may include a second plurality of array columns of the volatile memory array 135. In some implementations, the first DRAM sub-array may correspond to a lower DQ position of the DRAM array and the second DRAM sub-array may correspond to an upper DQ position of the DRAM array, or vice versa.

The memory system controller 115 may transmit the command address bit CA0 in the command address to indicate which data portion is being transmitted and thereby indicate to the volatile memory array 135 which array portion should store the data portion. For example, the memory system controller 115 may transmit two consecutive write commands on a command line to write the full amount of data (e.g., the data vector). The two consecutive write commands may include a first write command that includes a first command address with a first command address bit indicating that the first data portion is to be stored in a first portion of the volatile memory array 135. Additionally, the two consecutive write commands may include a second write command that includes a second command address with a second command address bit indicating that the second data portion is to be stored in a second portion of the volatile memory array 135. The first command address bit may be different from the second command address bit. For instance, the first command address bit may be a logic ‘0’ and the second command address bit may be a logic ‘1’, or vice versa.

During a read operation, the memory system controller 115 may transmit the command address bit CA0 in the command address to indicate which data portion is to be read from the volatile memory array 135 and thereby indicate to the volatile memory array 135 which array portion should be read to provide the data portion. Thus, the data may be stored and read from the volatile memory array 135 as the first data portion and the second data portion. The volatile memory array 135 may be configured to transfer the first data portion and the second data portion in consecutive bursts, with each data portion being transferred with respective parity bits (e.g., 8 parity bits based on a Hamming code+1 single parity-check bit).

The memory system controller 115 may transmit two consecutive read commands on the command line to read the full amount of data (e.g., the data vector). The two consecutive read commands may include a first read command that includes a first command address with a first command address bit indicating that the first data portion is to be read from the volatile memory array 135. Additionally, the two consecutive write commands may include a second read command that includes a second command address with a second command address bit indicating that the second data portion is to be read from the volatile memory array 135. The first command address bit may be different from the second command address bit. For instance, the first command address bit may be a logic ‘0’ and the second command address bit may be a logic ‘1’, or vice versa.

Although the example memory system 110 described above includes a memory system controller 115, in some implementations, the memory system 110 does not include a memory system controller 115. For example, an external controller (e.g., included in the host system 105) and/or one or more local controllers 125 included in one or more corresponding memory devices 120 may perform the operations described herein as being performed by the memory system controller 115. Furthermore, as used herein, a “controller” may refer to the memory system controller 115, a local controller 125, or an external controller. In some implementations, a set of operations described herein as being performed by a controller may be performed by a single controller. For example, the entire set of operations may be performed by a single memory system controller 115, a single local controller 125, or a single external controller. Alternatively, a set of operations described herein as being performed by a controller may be performed by more than one controller. For example, a first subset of the operations may be performed by the memory system controller 115 and a second subset of the operations may be performed by a local controller 125. Furthermore, the term “memory apparatus” may refer to the memory system 110 or a memory device 120, depending on the context.

A controller (e.g., the memory system controller 115, a local controller 125, or an external controller) may control operations performed on memory (e.g., a memory array 130), such as by executing one or more instructions. For example, the memory system 110 and/or a memory device 120 may store one or more instructions in memory as firmware, and the controller may execute those one or more instructions. Additionally, or alternatively, the controller may receive one or more instructions from the host system 105 and/or from the memory system controller 115, and may execute those one or more instructions. In some implementations, a non-transitory computer-readable medium (e.g., volatile memory and/or non-volatile memory) may store a set of instructions (e.g., one or more instructions or code) for execution by the controller. The controller may execute the set of instructions to perform one or more operations or methods described herein. In some implementations, execution of the set of instructions, by the controller, causes the controller, the memory system 110, and/or a memory device 120 to perform one or more operations or methods described herein. In some implementations, hardwired circuitry is used instead of or in combination with the one or more instructions to perform one or more operations or methods described herein. Additionally, or alternatively, the controller may be configured to perform one or more operations or methods described herein. An instruction is sometimes called a “command.”

For example, the controller (e.g., the memory system controller 115, a local controller 125, or an external controller) may transmit signals to and/or receive signals from memory (e.g., one or more memory arrays 130) based on the one or more instructions, such as to transfer data to (e.g., write or program), to transfer data from (e.g., read), to erase, and/or to refresh all or a portion of the memory (e.g., one or more memory cells, pages, sub-blocks, blocks, or planes of the memory). Additionally, or alternatively, the controller may be configured to control access to the memory and/or to provide a translation layer between the host system 105 and the memory (e.g., for mapping logical addresses to physical addresses of a memory array 130). In some implementations, the controller may translate a host interface command (e.g., a command received from the host system 105) into a memory interface command (e.g., a command for performing an operation on a memory array 130).

In some examples, the system 100 may be associated with a CXL standard and/or protocol (e.g., the system 100 may utilize a CXL protocol to communicate between the host system 105, sometimes referred to as a CXL compliant host or simply a CXL host, and the memory system 110, sometimes referred to as a CXL compliant memory system or simply a CXL memory system). In that regard, the host system 105 may be a CXL host and the memory system 110 may be a CXL compliant memory system. The CXL host and the CXL compliant memory system may communicate via the host interface 140, which may include a CXL bus (e.g., a PCIe/CXL interface, an Ultra Accelerator link (UALink) interface, an Ethernet interface, an ultra-Ethernet interface, and/or a similar interface), among other examples.

In some examples, the memory system 110 may be a system that complies with the CXL standard and/or protocol, such as for a purpose of communicating with one or more host devices (e.g., the host system 105). CXL is an open standard that may enable high-speed CPU-to-device and CPU-to-memory interconnects designed to accelerate next-generation performance. The CXL standard may enable memory coherency between the CPU memory space and memory on attached devices, which allows resource sharing for higher performance, reduced software stack complexity, and lower overall system cost. CXL is designed to be an industry open standard for enabling an interface for high-speed communications. CXL technology utilizes the PCIe infrastructure, leveraging PCIe physical and electrical interfaces to provide an advanced protocol in areas such as input/output (I/O) protocol, memory protocol, and coherency interface.

In some implementations, one or more systems, devices, apparatuses, components, and/or controllers of FIG. 1 may include a communication interface including a plurality of data lines configured to transmit data according to an x4-mode configuration, and a command line configured to transmit a command address that includes a command address bit; and split the data into a first data portion and a second data portion, generate first parity bits based on a first data portion and a transpose of a first reduced parity matrix corresponding to the first data portion, generate a first packet that includes the first data portion and the first parity bits, generate second parity bits based on a second data portion and a transpose of a second reduced parity matrix corresponding to the second data portion, generate a second packet that includes the second data portion and the second parity bits, and transmit the first packet and the second packet in two consecutive bursts, including transmitting the first data portion in a first burst of the two consecutive bursts on the plurality of data lines and transmitting the second data portion in a second burst of the two consecutive bursts on the plurality of data lines.

In some implementations, one or more systems, devices, apparatuses, components, and/or controllers of FIG. 1 may include a DRAM array including a first DRAM sub-array configured to store a first data portion of data and a second DRAM sub-array configured to store a second data portion of the data; a communication interface including a plurality of data lines configured to transmit the data according to an x4-mode configuration, and a command line configured to receive a command address that includes a command address bit; and generate first parity bits based on the first data portion and a transpose of a first reduced parity matrix corresponding to the first data portion, generate a first packet that includes the first data portion and the first parity bits, generate second parity bits based on the second data portion and a transpose of a second reduced parity matrix corresponding to the second data portion, generate a second packet that includes the second data portion and the second parity bits, and transmit the first packet and the second packet in two consecutive bursts, including transmitting the first data portion in a first burst of the two consecutive bursts on the plurality of data lines and transmitting the second data portion in a second burst of the two consecutive bursts on the plurality of data lines.

In some implementations, one or more systems, devices, apparatuses, components, and/or controllers of FIG. 1 may include a memory controller comprising one or more first processors; a memory device comprising one or more second processors and a DRAM array including a first DRAM sub-array configured to store a first data portion of a first data vector and a second DRAM sub-array configured to store a second data portion of the first data vector; and a communication link coupled to the memory controller and the memory device for transferring data vectors between the memory controller and the DRAM array, wherein the communication link includes a plurality of data lines configured to transmit respective data vectors according to an x4-mode configuration, and a command line configured to transmit a command address that includes a command address bit from the memory controller to the memory device, wherein the one or more first processors are configured to transmit the first data vector to the memory device during a write operation, including: split the first data vector into the first data portion and the second data portion, generate first parity bits based on a first vector matrix multiplication of the first data portion and a transpose of a first reduced parity matrix corresponding to the first data portion, generate a first packet that includes the first data portion and the first parity bits, generate second parity bits based on a first vector matrix multiplication of the second data portion and a transpose of a second reduced parity matrix corresponding to the second data portion, generate a second packet that includes the second data portion and the second parity bits, and transmit the first packet and the second packet in a first sequence of consecutive bursts to the memory device, including transmitting, on the plurality of data lines, the first data portion in a first burst in the first sequence of consecutive bursts and transmitting, on the plurality of data lines, the second data portion in a second burst in the first sequence of consecutive bursts on the plurality of data lines. The one or more second processors are configured to transmit the first data vector to the memory controller during a read operation, including: generating third parity bits based on the first data portion read from the first DRAM sub-array and the transpose of the first reduced parity matrix corresponding to the first data portion, generating a third packet that includes the first data portion and the third parity bits, generating fourth parity bits based on the second data portion read from the second DRAM sub-array and the transpose of the second reduced parity matrix corresponding to the second data portion, generating a fourth packet that includes the second data portion and the fourth parity bits, and transmitting the third packet and the fourth packet in a second sequence of consecutive bursts, including transmitting, on the plurality of data lines, the first data portion in a first burst in the second sequence of consecutive bursts and transmitting, on the plurality of data lines, the second data portion in a second burst in the second sequence of consecutive bursts.

In some implementations, one or more systems, devices, apparatuses, components, and/or controllers of FIG. 1 may be configured to segment the data vector into a first data portion and a second data portion; generate first parity bits based on the first data portion and a transpose of a first reduced parity matrix corresponding to the first data portion; generate a first packet that includes the first data portion and the first parity bits; generate second parity bits based on the second data portion and a transpose of a second reduced parity matrix corresponding to the second data portion; generate a second packet that includes the second data portion and the second parity bits; and transmit the first packet and the second packet in two consecutive bursts according to the x4-mode configuration, including transmitting the first data portion in a first burst of the two consecutive bursts on a plurality of data lines according to the x4-mode configuration, and transmitting the second data portion in a second burst of the two consecutive bursts on the plurality of data lines according to the x4-mode configuration.

The number and arrangement of components shown in FIG. 1 are provided as an example. In practice, there may be additional components, fewer components, different components, or differently arranged components than those shown in FIG. 1. Furthermore, two or more components shown in FIG. 1 may be implemented within a single component, or a single component shown in FIG. 1 may be implemented as multiple, distributed components. Additionally, or alternatively, a set of components (e.g., one or more components) shown in FIG. 1 may perform one or more operations described as being performed by another set of components shown in FIG. 1.

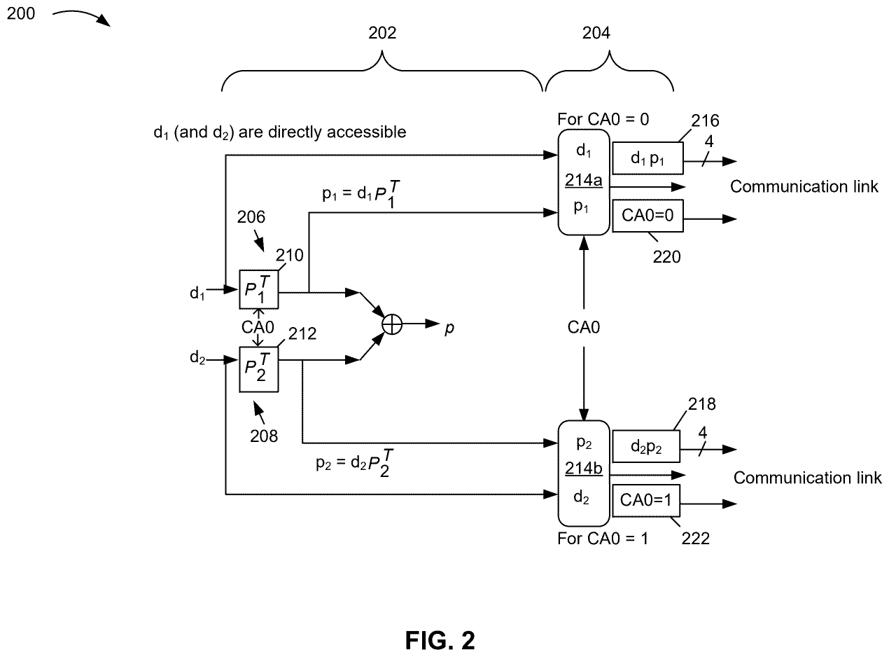

FIG. 2 shows an example of a link ECC circuit 200 of a memory controller according to one or more implementations. The link ECC circuit 200 may include a parity computation stage 202 and a communication stage 204. The link ECC circuit 200 may include one or more processors configured to perform parity computations and generate packets for transmission via a communication link, such as an LPDDR5 link. Moreover, the memory controller may correspond to the memory system controller 115 described in connection with FIG. 1.

The memory controller may split data d to be written to a memory device (e.g., a DRAM array) into a first data portion d₁ and a second data portion d₂. The data d may be a 128-bit data vector, the first data portion d₁ may be a first half of the 128-bit data vector, including bits 1-64, and the second data portion d₂ may be a second half of the 128-bit data vector, including bits 65-128. Thus, the first data portion d₁ may be a first data sub-vector (e.g., a first 64-bit data vector), the second data portion d₂ may be a second data sub-vector (e.g., a second 64-bit data vector), and the first data sub-vector and the second data sub-vector may correspond to respective first and second halves of the 128-bit data vector.

The link ECC circuit 200 may receive the first data portion d₁ and the second data portion d₂ and compute respective parity bits for each data portion. In addition, the communication stage 204 may receive the first data portion d₁ and the second data portion d₂ for transmission. In other words, the first data portion d₁ and the second data portion d₂ may be directly accessible by the communication stage 204.

The link ECC circuit 200 may include a first processing path 206 for the first data portion d₁ and a second processing path 208 for the second data portion d₂. The first processing path 206 may include a first processing element 210 (e.g., a processor) configured to generate first parity bits p₁ based on the first data portion d₁ and a transpose

$${P}_{1}^{T}$$

of a first reduced parity matrix P1 corresponding to the first data portion d₁. For example, the first parity bits p₁ may be generated based on a matrix multiplication of the first data portion d₁ and the transpose of the first reduced parity

$${P}_{1}^{T}$$

of the first reduced parity matrix P1.

The second processing path 208 may include a second processing element 212 (e.g., a processor) configured to generate second parity bits p₂ based on the second data portion d₂ and a transpose

$${P}_{2}^{T}$$

of a second reduced parity matrix P2 corresponding to the second data portion d₂. For example, the second parity bits p₂ may be generated based on a matrix multiplication of the second data portion d₂ and the transpose

$${P}_{2}^{T}$$

of the second reduced parity matrix P2. The first processing element 210 and the second processing element 212 may be part of a same processor or may be provided as different processors.

Parity bits p of the data d are equal to a sum of the first parity bits p₁ and the second parity bits p₂. In other words,

$$p = {dP}^{T} = {d}_{1} {P}_{1}^{T} + {d}_{2} {P}_{2}^{T} = {p}_{1} + {p}_{2} ,$$

where P^{T} is a transpose of a full parity matrix P (e.g., an 8×128 parity matrix) that corresponds to the data d, and p may be representative of a parity vector (8-bit) for the full data vector d. Thus, the first reduced parity matrix P1 and the second reduced parity matrix P2 may be respective halves of the full parity matrix P (e.g., 8×64 parity matrices). The first reduced parity matrix P1 may include columns corresponding to bit positions of the first data portion d₁ within the data d. The second reduced parity matrix P2 may include columns corresponding to bit positions of the second data portion d₂ within the data d.

The link ECC circuit 200 may derive the first reduced parity matrix P1 and the second reduced parity matrix P2 from a parity check matrix H used for 128-bit data transmissions, such that the first reduced parity matrix P1 and the second reduced parity matrix P2 are compatible with respective 64-bit data transmissions in the x4-mode configuration. For example, the parity check matrix H may be an 8×136 matrix, with H=[I, P], where I is an 8×8 identity matrix and P=[P1, P2].

The link ECC circuit 200 may perform encoding with P1 (e.g., if the command address bit CA0=0) or with P2 (e.g., if the command address bit CA0=1). Thus, the link ECC circuit 200 may selectively use the first reduced parity matrix P1 or the second reduced parity matrix P2 based on the command address bit CA0 to generate the first parity bits p₁ or the second parity bits p₂, respectively.

The communication stage 204 may include one or more communication processors 214a and 214b for generating transmission packets based on the command address bit CA0. For example, the communication processor 214a may generate a first packet 216 that includes the first data portion d₁ and the first parity bits p₁. Additionally, the communication processor 214b may generate a second packet 218 that includes the second data portion d₂ and the second parity bits p₂. The communication processors 214a and 214b may transmit the first packet 216 and the second packet 218 in a first sequence of two consecutive bursts to a memory device (e.g., memory device 120), including transmitting the first data portion d₁ in a first burst of the two consecutive bursts on a plurality of data lines of the communication link (e.g., DQ lines), and transmitting the second data portion d₂ in a second burst of the two consecutive bursts on the plurality of data lines. In some implementations, the first burst and the second burst each have a burst length of 16 clock cycles or beats. The plurality of data lines may be configured to transmit the data portions according to an x4-mode configuration.

The communication processors 214a and 214b may selectively transmit the first packet or the second packet based on the command address bit CA0. For example, the communication processor 214a may transmit the first packet 216 when CA0=0, and the communication processor 214b may transmit the second packet 218 when CA0=1. In addition, the communication processors 214a and 214b may transmit, on a command line, write commands associated with the first data portion d₁ and the second data portion d₂. For example, the communication processor 214a may transmit a first write command 220 associated with the first packet 216 when the first data portion d₁ is to be written into memory, and the communication processor 214a may transmit a second write command 222 associated with the second packet 218 when the second data portion d₂ is to be written into memory. The first write command 220 and the second write command 222 may be transmitted as consecutive write commands that correspond to a single write operation for writing data d (e.g., a single write operation for the full data vector).

The first write command 220 may include a first command address and the second write command 222 may include a second command address. The communication processor 214a may transmit, on the command line, the first command address with a first command address bit (e.g., CA0=0) indicating that the first data portion is to be stored in a first portion of a memory array of a memory device. The communication processor 214b may transmit, on the command line, the second command address with a second command address bit (e.g., CA0=1) indicating that the second data portion is to be stored in a second portion of the memory array of the memory device. Thus, different command address bits may be provided in the two write commands in order to write the first data portion and the second data portion into respective portions of the memory array.

The packets 216 and 218 may be transmitted after the write commands 220 and 222, respectively. For example, there may exist some write latency between sending a write command and a corresponding packet. The write latency may provide the memory device with sufficient time to process the write command and prepare for receiving and processing the corresponding packet.

The number and arrangement of components shown in FIG. 2 are provided as an example. In practice, there may be additional components, fewer components, different components, or differently arranged components than those shown in FIG. 2. Furthermore, two or more components shown in FIG. 2 may be implemented within a single component, or a single component shown in FIG. 2 may be implemented as multiple, distributed components. Additionally, or alternatively, a set of components (e.g., one or more components) shown in FIG. 2 may perform one or more operations described as being performed by another set of components shown in FIG. 2.

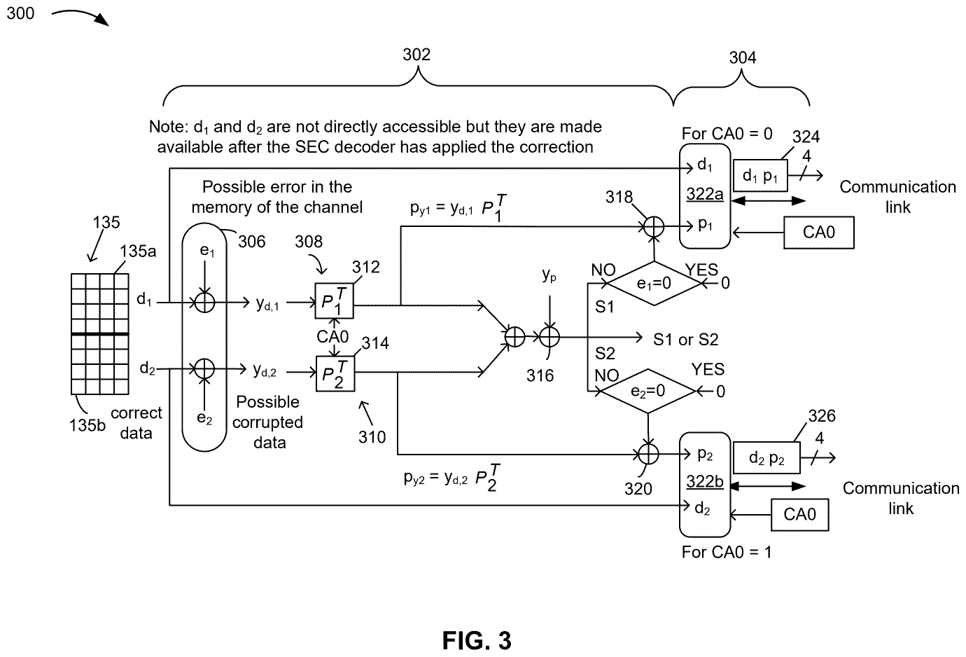

FIG. 3 shows an example of a link ECC circuit 300 of a memory device according to one or more implementations. The link ECC circuit 300 may include a parity and syndrome computation stage 302 and a communication stage 304. The link ECC circuit 300 may include one or more processors configured to perform parity computations and syndrome computations, and to generate packets for transmission via a communication link, such as an LPDDR5 link. The link ECC circuit 300 may be part of an SEC decoder. Moreover, the memory device may correspond to the memory device 120 described in connection with FIG. 1. The link ECC circuit 300 may be integrated into the local controller 125. Memory of the memory device into which data is being written to or read from may be the volatile memory array 135, such as a DRAM array. As described above, the memory device 120 may include the volatile memory array 135. The volatile memory array 135 may include a first DRAM sub-array 135a configured to store the first data portion d₁ of data d and a second DRAM sub-array 135b configured to store the second data portion d₂ of data d.

The link ECC circuit 300 may be a counterpart circuit to the link ECC circuit 200 described in connection with FIG. 2. Thus, the communication link of the link ECC circuit 300 may include a plurality of data lines configured to transmit data portions according to an x4-mode configuration. In addition, the link ECC circuit 300 may be configured to transmit or receive data portions with a burst length of 16 clock cycles or beats.

The link ECC circuit 300 may receive the first data portion d₁ and the second data portion d₂ from the volatile memory array 135 and compute respective parity bits for each data portion. In addition, the communication stage 304 may receive the first data portion d₁ and the second data portion d₂ for transmission. The communication stage 304 may receive the first data portion d₁ and the second data portion d₂ for transmission after the SEC decoder performs any needed corrections to the data portions. For example, the link ECC circuit 300 may include respective memory channels 306 used for transferring the first data portion d₁ and the second data portion d₂ to the parity and syndrome computation stage 302. Errors e1 and e2 may be introduced in the first data portion d₁ and the second data portion d₂ via the respective memory channels 306. Thus, the SEC decoder may detect and correct the errors e1 and e2 prior to providing the first data portion d₁ and the second data portion d₂ to the communication stage 304.

The parity and syndrome computation stage 302 may compute a syndrome S. The syndrome S is a vector used to detect and locate errors in a received codeword y. The syndrome S may be derived by performing matrix multiplication of the received codeword y with the transpose HT of the parity check matrix H.

$$S = {yH}^{T} = [ {y}_{p} {y}_{d} ] [ \begin{matrix}1 \\ {P}^{T}\end{matrix} ] = {y}_{p} + {y}_{d} {P}^{T}$$

Here, yₚ represents a received parity (e.g., parity bits of correct data), y_{d} represents received data (which may be corrupted), and y_{d}P^{T} represents a parity computed using received data (e.g., parity bits of data with potential errors). When no errors are present in the received data, the syndrome is zero. Thus, the syndrome S represents a discrepancy between yₚ and y_{d}P^{T}. Stated differently, the syndrome S may be represented by the following equation.

$$S = [ p , d ] {H}^{T} = p + {dP}^{T} = p + {d}_{1} P {1}^{T} + {d}_{2} P {2}^{T} = p + {p}_{1} + {p}_{2} .$$

Here, P1^{T} represents a transpose of the first reduced parity matrix P1, and P2^{T} represents a transpose of the second reduced parity matrix P2. Data with an error may be referred to as corrupted data.

The parity and syndrome computation stage 302 may perform a parity adjustment on a computed parity when a data portion d₁ or d₂ is corrupted. If p=dP^{T}, then a parity of corrupted data pₑ=(d+e)P^{T}=dP^{T}+eP^{T}=p+eP^{T}. In other words, the parity pₑ of corrupted data with error e, is equal to the parity without the error e adjusted with the term eP^{T}. Thus, a syndrome S with error on data is: S=p+(d+e)P^{T}=eP^{T}. This means that pₑ=p+S, or that the parity pₑ of a data with error e is the parity p without the error e adjusted with the syndrome value S. Consequently, p=pₑ+S, the parity p of corrected data can be obtained by adding the syndrome S to the parity pₑ of the corrupted data. If the data d is split into two sub-vectors d₁ and d₂, the statement is preserved for the two sub-vectors:

$${p}_{1} = {p}_{e 1} + S , if the data {d}_{1} is corrupted ,$$

$${p}_{2} = {p}_{e 2} + S , if the data {d}_{2} is corrupted ,$$

with pₑ₁ representing a parity of corrupted data portion d₁, and pₑ₂ representing a parity of corrupted data portion d₂. Thus, a parity (e.g., pₑ or pₑ₂) of a corrupted data portion may be adjusted by adding the syndrome S associated with the corrupted data portion to the parity (e.g., pₑ₁ or pₑ₂) to obtain a corrected parity (e.g., p₁ or p₂, respectively).

The link ECC circuit 300 may include a first processing path 308 for the first data portion d₁ and a second processing path 310 for the second data portion d₂. The first data portion d₁ may be corrupted with an error e1. Thus, the first data portion d₁ is represented as y_{d,1} in the first processing path 308. The second data portion d₂ may be corrupted with an error e2. Thus, the second data portion d₂ is represented as y_{d,2} in the second processing path 310.

The first processing path 308 may include a first processing element 312 (e.g., a processor) configured to generate first parity bits p_{y1} based on the first data portion y_{d,1} and a transpose

$${P}_{1}^{T}$$

of a first reduced parity matrix P1 corresponding to the first data portion d₁. For example, the first parity bits p_{y1} may be generated based on a matrix multiplication of the first data portion y_{d,1} and the transpose

$${P}_{1}^{T}$$

of the first reduced parity matrix P1.

The second processing path 310 may include a second processing element 314 (e.g., a processor) configured to generate second parity bits p_{y2} based on the second data portion y_{d,2} and a transpose

$${P}_{2}^{T}$$

of a second reduced parity matrix P2 corresponding to the second data portion d₂. For example, the second parity bits p_{y2} may be generated based on a matrix multiplication of the second data portion y_{d,2} and the transpose

$${P}_{2}^{T}$$

of the second reduced parity matrix P2. The first processing element 312 and the second processing element 314 may be part of a same processor or may be provided as different processors. However, only the first data portion d₁ or the second data portion d₂ is read from memory and processed at a time, for example, based on the command address bit CA0. Thus, the first data portion d₁ or the second data portion d₂ are read from memory and processed sequentially.

The parity and syndrome computation stage 302 may check a syndrome S to determine whether a parity adjustment on a computed parity should be performed. For example, after the first parity bits p_{y1} are generated, a combiner 316 may calculate a first syndrome vector S1 corresponding to the first data portion d₁ using the first parity bits p_{y1} and first correct parity bits yₚ₁ (e.g., S1=yₚ₁+p_{y1}). Thus, the combiner 316 may calculate the first syndrome vector S1 by adding the first parity bits p_{y1} and the first correct parity bits yₚ₁. The parity and syndrome computation stage 302 may determine whether the first syndrome vector S1 indicates an error or indicates no error by comparing the first syndrome vector S1 to zero.

If the first syndrome vector S1 is zero, then no error is present and the first parity bits p_{y1} and the first data portion y_{d,1} are error-free. If the first syndrome vector S1 is zero, no parity adjustment is needed. Thus, a combiner 318 may be configured to add zero to the first parity bits p_{y1} to obtain parity p₁. Put another way, the first parity bits p_{y1} may be passed on to the communication stage 304 without adjustment.

If the first syndrome vector S1 is non-zero, an error is present in the first parity bits p_{y1} as a result of error e1 being present in the first data portion y_{d,1}. Based on the first syndrome vector S1 being non-zero, the combiner 318 may be configured to add the first syndrome vector S1 to the first parity bits p_{y1} to obtain parity p₁, which includes corrected parity bits. In other words, based on the first syndrome vector S1 indicating an error, the parity and syndrome computation stage 302 may update the first parity bits p_{y1} using the first syndrome vector S1 to generate first corrected parity bits p₁. The combiner 318 may generate the first corrected parity bits by adding the first parity bits p_{y1} and the first syndrome vector S1.

After the second parity bits p_{y2} are generated, the combiner 316 may calculate a second syndrome vector S2 corresponding to the second data portion d₂ using the second parity bits p_{y2} and second correct parity bits yₚ₂ (e.g., S2=yₚ₂+p_{y2}). Thus, the combiner 316 may calculate the second syndrome vector S1 by adding the second parity bits p_{y2} and the second correct parity bits yₚ₂. The parity and syndrome computation stage 302 may determine whether the second syndrome vector S2 indicates an error or indicates no error by comparing the second syndrome vector S2 to zero.

If the second syndrome vector S2 is zero, then no error is present and the second parity bits p_{y2} and the second data portion y_{d,2} are error-free. If the second syndrome vector S2 is zero, no parity adjustment is needed. Thus, a combiner 320 may be configured to add zero to the second parity bits p_{y2} to obtain parity p₂. Put another way, the second parity bits p_{y2} may be passed on to the communication stage 304 without adjustment.

If the second syndrome vector S2 is non-zero, an error is present in the second parity bits p_{y2} as a result of error e2 being present in the second data portion y_{d,2}. Based on the second syndrome vector S2 being non-zero, the combiner 320 may be configured to add the second syndrome vector S2 to the second parity bits p_{y2} to obtain parity p₂, which includes corrected parity bits. In other words, based on the second syndrome vector S2 indicating an error, the parity and syndrome computation stage 302 may update the second parity bits p_{y2} using the second syndrome vector S2 to generate second corrected parity bits p₂. The combiner 320 may generate the second corrected parity bits by adding the second parity bits p_{y2} and the second syndrome vector S1.

In some implementations, the parity and syndrome computation stage 302 may generate first correct parity bits yₚ₁ based on a first correct data portion from which the first data portion d₁ is derived, compute a first syndrome vector S1 based on the first parity bits p_{y1} and the first correct parity bits yₚ₁, correct the first parity bits yₚ₁, for transmission in the first packet 324, based on the first syndrome vector S1 indicating an error in the first parity bits p_{y1}, generate second correct parity bits yₚ₂ based on a second correct data portion from which the second data portion d₂ is derived, compute a second syndrome vector S2 based on the second parity bits p_{y2} and the second correct parity bits yₚ₂, and correct the second parity bits p_{y2}, for transmission in the second packet 326, based on the second syndrome vector S1 indicating an error in the second parity bits p_{y2}.

The communication stage 304 may include one or more communication processors 322a and 322b for generating transmission packets based on the command address bit CA0. The communication processor 322a may generate a first packet 324 that includes the first data portion d₁ and the first parity bits p₁. Based on the first syndrome vector S1 indicating that no error is present, the communication processor 322a may transmit the first packet 324 with the first parity bits p_{y1} (e.g., p₁=p_{y1}). Alternatively, based on the first syndrome vector S1 indicating an error, the communication processor 322a may transmit the first packet 324 with the first corrected parity bits (e.g., p₁=p_{y1}+S1).

The communication processor 322b may generate a second packet 326 that includes the second data portion d₂ and the second parity bits p₂. Based on the second syndrome vector S2 indicating that no error is present, the communication processor 322b may transmit the second packet 326 with the second parity bits p_{y2} (e.g., p₂=p_{y2}). Alternatively, based on the second syndrome vector S2 indicating an error, the communication processor 322b may transmit the second packet 326 with the second corrected parity bits (e.g., p₂=p_{y2}+S2).

The communication processors 322a and 322b may transmit the first packet 324 and the second packet 326 in a second sequence of two consecutive bursts to a memory controller (e.g., memory system controller 115), including transmitting the first data portion d₁ in a first burst of the two consecutive bursts on a plurality of data lines of the communication link (e.g., DQ lines), and transmitting the second data portion d₂ in a second burst of the two consecutive bursts on the plurality of data lines. In some implementations, the first burst and the second burst each have a burst length of 16 clock cycles or beats. The plurality of data lines may be configured to transmit the data portions according to an x4-mode configuration.

The communication processors 322a and 322b may selectively transmit the first packet or the second packet based on the command address bit CA0. For example, the communication processor 322a may transmit the first packet 324 when CA0=0, and the communication processor 322b may transmit the second packet 326 when CA0=1. In addition, the communication processors 322a and 322b may receive, on a command line, read commands associated with the first data portion d₁ and the second data portion d₂. The read commands may be received as consecutive read commands that correspond to a single read operation for reading data d (e.g., a single read operation for the full data vector). The communication processors 322a and 322b may receive a first read command associated with the first data portion d₁ when the first data portion d₁ is to be read from memory. The communication processors 322a and 322b may receive a second read command associated with the second data portion d₂ when the second data portion d₂ is to be read from memory. Each read command may include a respective command address that includes the command address bit that specifics which data portion is to be read from memory and packetized for transmission.

The number and arrangement of components shown in FIG. 3 are provided as an example. In practice, there may be additional components, fewer components, different components, or differently arranged components than those shown in FIG. 3. Furthermore, two or more components shown in FIG. 3 may be implemented within a single component, or a single component shown in FIG. 3 may be implemented as multiple, distributed components. Additionally, or alternatively, a set of components (e.g., one or more components) shown in FIG. 3 may perform one or more operations described as being performed by another set of components shown in FIG. 3.

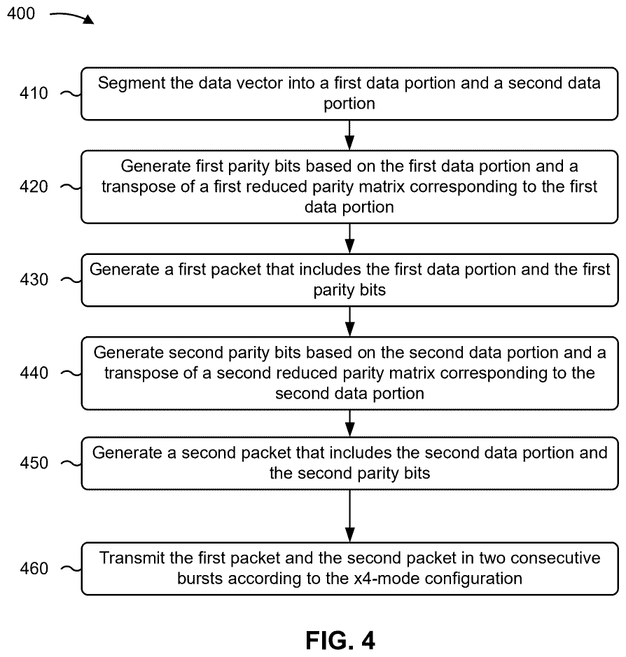

FIG. 4 is a flowchart of an example method 400 associated with link error correction code parity generation in x4-mode for dynamic random-access memory. In some implementations, a memory controller or memory device (e.g., the memory system controller 115 or memory device 120) may perform or may be configured to perform the method 400. In some implementations, another device or a group of devices separate from or including the memory controller or memory device (e.g., the system 100) may perform or may be configured to perform the method 400. Additionally, or alternatively, one or more components of the memory controller or the memory device may perform or may be configured to perform the method 400. Thus, means for performing the method 400 may include the memory controller or the memory device and/or one or more components of the memory controller or the memory device. Additionally, or alternatively, a non-transitory computer-readable medium may store one or more instructions that, when executed by the memory controller or the memory device, cause the memory controller or the memory device to perform the method 400.

As shown in FIG. 4, the method 400 may include segmenting the data vector into a first data portion and a second data portion (block 410). As further shown in FIG. 4, the method 400 may include generating first parity bits based on the first data portion and a transpose of a first reduced parity matrix corresponding to the first data portion (block 420). As further shown in FIG. 4, the method 400 may include generating a first packet that includes the first data portion and the first parity bits (block 430). As further shown in FIG. 4, the method 400 may include generating second parity bits based on the second data portion and a transpose of a second reduced parity matrix corresponding to the second data portion (block 440). As further shown in FIG. 4, the method 400 may include generating a second packet that includes the second data portion and the second parity bits (block 450). As further shown in FIG. 4, the method 400 may include transmitting the first packet and the second packet in two consecutive bursts according to the x4-mode configuration (block 460). Transmitting the first packet and the second packet may include transmitting the first data portion in a first burst of the two consecutive bursts on a plurality of data lines according to the x4-mode configuration, and transmitting the second data portion in a second burst of the two consecutive bursts on the plurality of data lines according to the x4-mode configuration.

The method 400 may include additional aspects, such as any single aspect or any combination of aspects described in connection with one or more other methods or operations described elsewhere herein.

Although FIG. 4 shows example blocks of a method 400, in some implementations, the method 400 may include additional blocks, fewer blocks, different blocks, or differently arranged blocks than those depicted in FIG. 4. Additionally, or alternatively, two or more of the blocks of the method 400 may be performed in parallel. The method 400 is an example of one method that may be performed by one or more devices described herein. These one or more devices may perform or may be configured to perform one or more other methods based on operations described herein.

In some implementations, a memory controller includes a communication interface including a plurality of data lines configured to transmit data according to an x4-mode configuration, and a command line configured to transmit a command address that includes a command address bit; and one or more processors configured to: split the data into a first data portion and a second data portion, generate first parity bits based on a first data portion and a transpose of a first reduced parity matrix corresponding to the first data portion, generate a first packet that includes the first data portion and the first parity bits, generate second parity bits based on a second data portion and a transpose of a second reduced parity matrix corresponding to the second data portion, generate a second packet that includes the second data portion and the second parity bits, and transmit the first packet and the second packet in two consecutive bursts, including transmitting the first data portion in a first burst of the two consecutive bursts on the plurality of data lines and transmitting the second data portion in a second burst of the two consecutive bursts on the plurality of data lines.

In some implementations, a memory device includes a DRAM array including a first DRAM sub-array configured to store a first data portion of data and a second DRAM sub-array configured to store a second data portion of the data; a communication interface including a plurality of data lines configured to transmit the data according to an x4-mode configuration, and a command line configured to receive a command address that includes a command address bit; and one or more processors configured to: generate first parity bits based on the first data portion and a transpose of a first reduced parity matrix corresponding to the first data portion, generate a first packet that includes the first data portion and the first parity bits, generate second parity bits based on the second data portion and a transpose of a second reduced parity matrix corresponding to the second data portion, generate a second packet that includes the second data portion and the second parity bits, and transmit the first packet and the second packet in two consecutive bursts, including transmitting the first data portion in a first burst of the two consecutive bursts on the plurality of data lines and transmitting the second data portion in a second burst of the two consecutive bursts on the plurality of data lines.

In some implementations, a memory system includes a memory controller comprising one or more first processors; a memory device comprising one or more second processors and a DRAM array including a first DRAM sub-array configured to store a first data portion of a first data vector and a second DRAM sub-array configured to store a second data portion of the first data vector; and a communication link coupled to the memory controller and the memory device for transferring data vectors between the memory controller and the DRAM array, wherein the communication link includes a plurality of data lines configured to transmit respective data vectors according to an x4-mode configuration, and a command line configured to transmit a command address that includes a command address bit from the memory controller to the memory device, wherein the one or more first processors are configured to transmit the first data vector to the memory device during a write operation, including: splitting the first data vector into the first data portion and the second data portion, generating first parity bits based on a first vector matrix multiplication of the first data portion and a transpose of a first reduced parity matrix corresponding to the first data portion, generating a first packet that includes the first data portion and the first parity bits, generating second parity bits based on a first vector matrix multiplication of the second data portion and a transpose of a second reduced parity matrix corresponding to the second data portion, generating a second packet that includes the second data portion and the second parity bits, and transmitting the first packet and the second packet in a first sequence of consecutive bursts to the memory device, including transmitting, on the plurality of data lines, the first data portion in a first burst in the first sequence of consecutive bursts and transmitting, on the plurality of data lines, the second data portion in a second burst in the first sequence of consecutive bursts on the plurality of data lines.

In some implementations, a method of transmitting a data vector according to an x4-mode configuration includes segmenting the data vector into a first data portion and a second data portion; generating first parity bits based on the first data portion and a transpose of a first reduced parity matrix corresponding to the first data portion; generating a first packet that includes the first data portion and the first parity bits; generating second parity bits based on the second data portion and a transpose of a second reduced parity matrix corresponding to the second data portion; generating a second packet that includes the second data portion and the second parity bits; and transmitting the first packet and the second packet in two consecutive bursts according to the x4-mode configuration, including transmitting the first data portion in a first burst of the two consecutive bursts on a plurality of data lines according to the x4-mode configuration, and transmitting the second data portion in a second burst of the two consecutive bursts on the plurality of data lines according to the x4-mode configuration.

The foregoing disclosure provides illustration and description but is not intended to be exhaustive or to limit the implementations to the precise forms disclosed. Modifications and variations may be made in light of the above disclosure or may be acquired from practice of the implementations described herein.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

When “a component” or “one or more components” (or another element, such as “a controller” or “one or more controllers”) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A memory controller, comprising:
a communication interface including a plurality of data lines configured to transmit data according to an x4-mode configuration, and a command line configured to transmit a command address that includes a command address bit; and
one or more processors configured to:
split the data into a first data portion and a second data portion,
generate first parity bits based on a first data portion and a transpose of a first reduced parity matrix corresponding to the first data portion,
generate a first packet that includes the first data portion and the first parity bits,
generate second parity bits based on a second data portion and a transpose of a second reduced parity matrix corresponding to the second data portion,
generate a second packet that includes the second data portion and the second parity bits, and
transmit the first packet and the second packet in two consecutive bursts, including transmitting the first data portion in a first burst of the two consecutive bursts on the plurality of data lines and transmitting the second data portion in a second burst of the two consecutive bursts on the plurality of data lines.

2. The memory controller of claim 1, wherein the one or more processors are configured to transmit, on the command line, a first command address with a first command address bit indicating that the first data portion is to be stored in a first portion of a memory array of a memory device,
wherein the one or more processors are configured to transmit, on the command line, a second command address with a second command address bit indicating that the second data portion is to be stored in a second portion of the memory array of the memory device, and
wherein the first command address bit is different from the second command address bit.

3. The memory controller of claim 1, wherein the one or more processors are configured to selectively transmit the first packet or the second packet based on the command address bit.

4. The memory controller of claim 1, wherein the one or more processors are configured to selectively use the first reduced parity matrix or the second reduced parity matrix based on the command address bit to generate the first parity bits or the second parity bits, respectively.

5. The memory controller of claim 1, wherein the first reduced parity matrix and the second reduced parity matrix are respective halves of a full parity matrix.

6. The memory controller of claim 5, wherein the first reduced parity matrix includes columns corresponding to bit positions of the first data portion within the data, and
wherein the second reduced parity matrix includes columns corresponding to bit positions of the second data portion within the data.

7. The memory controller of claim 1, wherein the one or more processors are configured to derive the first reduced parity matrix and the second reduced parity matrix from a parity check matrix used for 128-bit data transmissions such that the first reduced parity matrix and the second reduced parity matrix are compatible with respective 64-bit data transmissions in the x4-mode configuration.

8. The memory controller of claim 1, wherein the first burst and the second burst each have a burst length of 16 clock cycles.

9. The memory controller of claim 1, wherein the data is a 128-bit data vector, the first data portion is a first half of the 128-bit data vector, including bits 1-64, and the second data portion is a second half of the 128-bit data vector, including bits 65-128.

10. The memory controller of claim 1, wherein the data is a data vector, the first data portion is a first data sub-vector, the second data portion is a second data sub-vector, and the first data sub-vector and the second data sub-vector correspond to respective first and second halves of the data vector.

11. A memory device, comprising:
a dynamic random-access memory (DRAM) array including a first DRAM sub-array configured to store a first data portion of data and a second DRAM sub-array configured to store a second data portion of the data;
a communication interface including a plurality of data lines configured to transmit the data according to an x4-mode configuration, and a command line configured to receive a command address that includes a command address bit; and
one or more processors configured to:
generate first parity bits based on the first data portion and a transpose of a first reduced parity matrix corresponding to the first data portion,
generate a first packet that includes the first data portion and the first parity bits,
generate second parity bits based on the second data portion and a transpose of a second reduced parity matrix corresponding to the second data portion,
generate a second packet that includes the second data portion and the second parity bits, and
transmit the first packet and the second packet in two consecutive bursts, including transmitting the first data portion in a first burst of the two consecutive bursts on the plurality of data lines and transmitting the second data portion in a second burst of the two consecutive bursts on the plurality of data lines.

12. The memory device of claim 11, wherein the one or more processors are configured to selectively read out the first data portion of data from the first DRAM sub-array or the second data portion of data from the second DRAM sub-array based on the command address bit.

13. The memory device of claim 11, wherein the one or more processors are configured to selectively use the first reduced parity matrix or the second reduced parity matrix based on the command address bit to generate the first parity bits or the second parity bits, respectively.

14. The memory device of claim 11, wherein the one or more processors are configured to selectively transmit the first packet or the second packet based on the command address bit.

15. The memory device of claim 11, wherein the one or more processors are configured to derive the first reduced parity matrix and the second reduced parity matrix from a parity check matrix used for 128-bit data transmissions such that the first reduced parity matrix and the second reduced parity matrix are compatible with respective 64-bit data transmissions in the x4-mode configuration.

16. The memory device of claim 11, wherein the data is 128 bits, the first data portion is a first half of the data and the second data portion is a second half of the data, and wherein the first burst and the second burst each have a burst length of 16 clock cycles.

17. The memory device of claim 11, wherein the one or more processors are configured to:
calculate a first syndrome vector corresponding to the first data portion using the first parity bits and first correct parity bits,
determine if the first syndrome vector indicates an error or indicates no error,
based on the first syndrome vector indicating no error, transmit the first packet with the first parity bits,
based on the first syndrome vector indicating an error, update the first parity bits to generate first corrected parity bits and transmit the first packet with the first corrected parity bits,
calculate a second syndrome vector corresponding to the second data portion using the second parity bits and second correct parity bits,
determine if the second syndrome vector indicates an error or indicated no error,
based on the second syndrome vector indicating no error, transmit the second packet with the second parity bits, and
based on the second syndrome vector indicating an error, update the second parity bits to generate second corrected parity bits and transmit the second packet with the second corrected parity bits.

18. The memory device of claim 17, wherein the one or more processors are configured to:
calculate the first syndrome vector by adding the first parity bits and the first correct parity bits, and
calculate the second syndrome vector by adding the second parity bits and the second correct parity bits.

19. The memory device of claim 17, wherein the one or more processors are configured to:
generate the first corrected parity bits by adding the first parity bits and the first syndrome vector, and
generate the second corrected parity bits by adding the second parity bits and the second syndrome vector.

20. The memory device of claim 11, wherein the one or more processors are configured to:
generate first correct parity bits based on a first correct data portion from which the first data portion is derived,
compute a first syndrome vector based on the first parity bits and the first correct parity bits,
correct the first parity bits, for transmission in the first packet, based on the first syndrome vector indicating an error in the first parity bits,
generate second correct parity bits based on a second correct data portion from which the second data portion is derived,
compute a second syndrome vector based on the second parity bits and the second correct parity bits, and
correct the second parity bits, for transmission in the second packet, based on the second syndrome vector indicating an error in the second parity bits.

21. The memory device of claim 11, wherein the first reduced parity matrix includes columns corresponding to bit positions of the first data portion within the data, and
wherein the second reduced parity matrix includes columns corresponding to bit positions of the second data portion within the data.

22. The memory device of claim 11, wherein the data is 128 bits, the first data portion is a first half of the data and the second data portion is a second half of the data,
wherein the first burst and the second burst each have a burst length of 16 clock cycles, and
wherein the plurality of data lines consist of four data lines.

23. A memory system, comprising:
a memory controller comprising one or more first processors;
a memory device comprising one or more second processors and a dynamic random-access memory (DRAM) array including a first DRAM sub-array configured to store a first data portion of a first data vector and a second DRAM sub-array configured to store a second data portion of the first data vector; and
a communication link coupled to the memory controller and the memory device for transferring data vectors between the memory controller and the DRAM array, wherein the communication link includes a plurality of data lines configured to transmit respective data vectors according to an x4-mode configuration, and a command line configured to transmit a command address that includes a command address bit from the memory controller to the memory device,
wherein the one or more first processors are configured to transmit the first data vector to the memory device during a write operation, including:
splitting the first data vector into the first data portion and the second data portion,
generating first parity bits based on a first vector matrix multiplication of the first data portion and a transpose of a first reduced parity matrix corresponding to the first data portion,
generating a first packet that includes the first data portion and the first parity bits,
generating second parity bits based on a first vector matrix multiplication of the second data portion and a transpose of a second reduced parity matrix corresponding to the second data portion,
generating a second packet that includes the second data portion and the second parity bits, and
transmitting the first packet and the second packet in a first sequence of consecutive bursts to the memory device, including transmitting, on the plurality of data lines, the first data portion in a first burst in the first sequence of consecutive bursts and transmitting, on the plurality of data lines, the second data portion in a second burst in the first sequence of consecutive bursts on the plurality of data lines.

24. The memory system of claim 23, wherein the one or more second processors are configured to transmit the first data vector to the memory controller during a read operation, including:
generating third parity bits based on the first data portion read from the first DRAM sub-array and the transpose of the first reduced parity matrix corresponding to the first data portion,
generating a third packet that includes the first data portion and the third parity bits,
generating fourth parity bits based on the second data portion read from the second DRAM sub-array and the transpose of the second reduced parity matrix corresponding to the second data portion,
generating a fourth packet that includes the second data portion and the fourth parity bits, and
transmitting the third packet and the fourth packet in a second sequence of consecutive bursts, including transmitting, on the plurality of data lines, the first data portion in a first burst in the second sequence of consecutive bursts and transmitting, on the plurality of data lines, the second data portion in a second burst in the second sequence of consecutive bursts.

25. A method of transmitting a data vector according to an x4-mode configuration, comprising:
segmenting the data vector into a first data portion and a second data portion;
generating first parity bits based on the first data portion and a transpose of a first reduced parity matrix corresponding to the first data portion;
generating a first packet that includes the first data portion and the first parity bits;
generating second parity bits based on the second data portion and a transpose of a second reduced parity matrix corresponding to the second data portion;
generating a second packet that includes the second data portion and the second parity bits; and
transmitting the first packet and the second packet in two consecutive bursts according to the x4-mode configuration, including transmitting the first data portion in a first burst of the two consecutive bursts on a plurality of data lines according to the x4-mode configuration, and transmitting the second data portion in a second burst of the two consecutive bursts on the plurality of data lines according to the x4-mode configuration.
